(19) United States
(12) Patent Application Publication
(10) Pub. No.: US 2002/0106877 A1
(43) Pub. Date: Aug. 8, 2002

(54) Method of fabricating a damascene structure

(76) Inventors: Chia-Lin Hsu, Taipei (TW); Teng-Chun Tsai, Hsinchu (TW); Yung-Tsung Wei, Tainan Hsien (TW); Hsueh-Chung Chen, Taipei Hsien (TW)

Correspondence Address: CHARLES C.H. WU & ASSOCIATES, Suite 710, 7700 IRVINE CENTER DRIVE, Irvine, CA, 92618-3043, US

(21) Appl. No.: 09/802,048

(22) Filed: Mar. 8, 2001

(30) Foreign Application Priority Data
Feb. 5, 2001 (TW) 90102333

(51) Int. Cl. H01L 21/3205

(52) U.S. Cl. 438/586

(57) ABSTRACT

A method of fabricating a damascene structure comprises of forming a dielectric layer on a substrate, and an opening is formed on the dielectric layer to expose a portion of the substrate. The dielectric layer is thus defined. A barrier layer is formed conformal to the profile of the opening and a metal layer fills the opening. Two chemical mechanical polishing processes are carried out sequentially to polish the metal layer and the barrier layer, wherein a first slurry is used to polish the metal layer and a second slurry that contains oxidant is used to polish the barrier layer. A damascene structure is thus formed.

### CROSS-REFERENCE TO RELATED APPLICATION

This application claims the priority benefit of Taiwan application serial no. 90102333, filed Feb. 5, 2001.

### BACKGROUND OF THE INVENTION

1. Field of Invention

The present invention that relates generally to a method of fabricating a multi-level interconnects of a semiconductor device. More particularly, the present invention relates to a method of fabricating a damascene structure.

2. Description of the Related Art

As the process of fabricating a semiconductor enter into a submicron technology, copper has replaced aluminum for wiring processes. Compared with aluminum, copper has a resistivity 30% lower and an electromigration resistivity 30 times or 100 times bigger than aluminum, thus forming a via contact with 10 to 20 times lower resistance.

Combined with the usage of low-K materials as the inter-metal dielectrics, the copper conductive wires can reduce the resistance capacitance (RC) delay and improve the electromigration characteristics. It is very difficult to perform etching on copper, so the copper damascene process has replaced the conventional etching process of fabricating the conductive wires.

For fabricating copper damascene, a copper chemical mechanical polishing (Cu CMP) technology is required. Because the hardness of copper is very low, the surface of the copper layer can be easily damaged by scratching during the fabricating process. On the other hand, the dielectric coefficient of the dielectric layer usually is lower than 3. Therefore, the organic polymers, having lower dielectric coefficient than the inorganic oxide or the nitride, are normally used for the inter-metal dielectric layer.

The low-K organic-polymer dielectric layer comprises a high percentage of carbon, so that carbon-rich particles may be produced during the Cu CMP process if the low-K dielectric material is exposed. The carbon-rich particle may adhere to the surface of the copper to cause process defects. The scratching and the adhesion can badly affect the reliability and performance of the device. Therefore, it is an object of the present invention to prevent the scratching and the adhesion of the carbon-rich particle on the copper surface.

### SUMMARY OF THE INVENTION

The present invention is to provide a method of fabricating a damascene structure to prevent carbon-rich particles adhering to a surface of a metal layer.

The present invention is to provide a method of fabricating a damascene structure to prevent scratching and defection of the metal layer during a polishing process.

Furthermore, the present invention is to provide a method of fabricating a damascene structure for improving the reliability and performance of a device.

It is an object of the present invention to provide a method of fabricating a damascene structure. A dielectric layer is formed on a provided substrate. The dielectric layer is defined to form an opening that exposes a portion of substrate. A barrier layer is formed conformally to the profile of the opening and a metal layer is next formed to fill the opening. A chemical mechanical polishing process is followed. A first slurry is used in the CMP process to remove a portion of the metal layer until the barrier layer is exposed. A second slurry that contains oxidant is used to remove a portion of the barrier layer outside the opening in the CMP process. A metal damascene structure is thus formed.

The characteristic of the present invention is to use the second slurry with oxidant for the barrier layer during the chemical mechanical polishing process, which can change the zeta potential of the metal layer when the oxidant reacts with the metal layer. Therefore, carbon-rich particles will not adhere on the surface of the metal layer and no scratching occurs on the metal surface. As a result, defects of the wafer can be reduced, and the reliability and performance of the device can be improved.

It is to be understood that both the forgoing general description and the following detailed description are exemplary, and are intended to provide further explanation of the invention as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIGS. 1A to 1D are the schematic diagrams of a method of fabricating a damascene structure according to one preferred embodiment of the present invention.

### DESCRIPTION OF THE PREFERRED EMBODIMENT

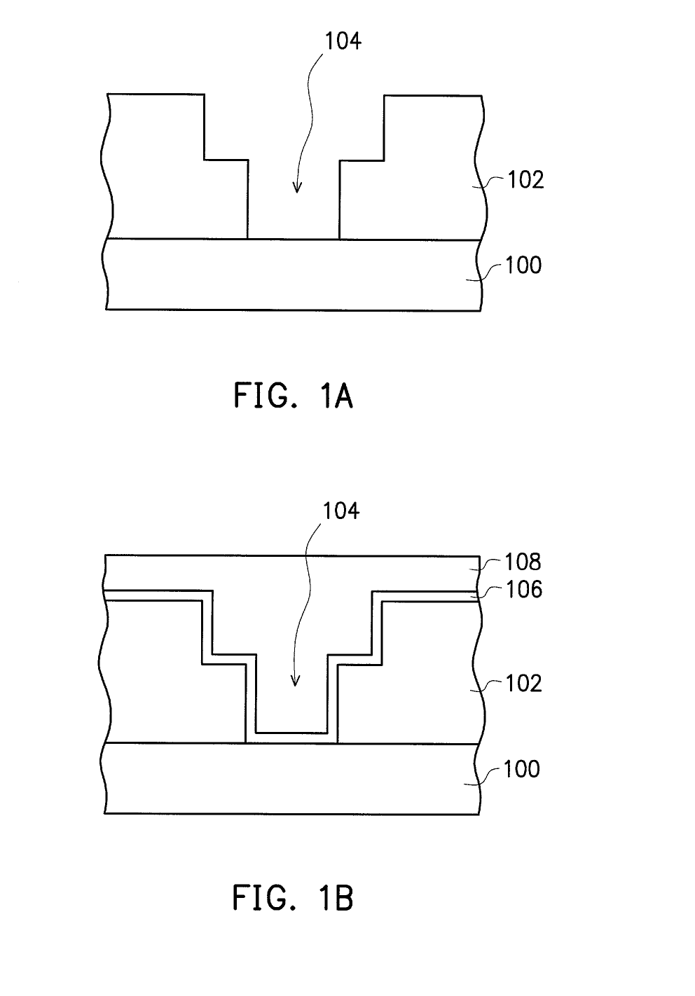

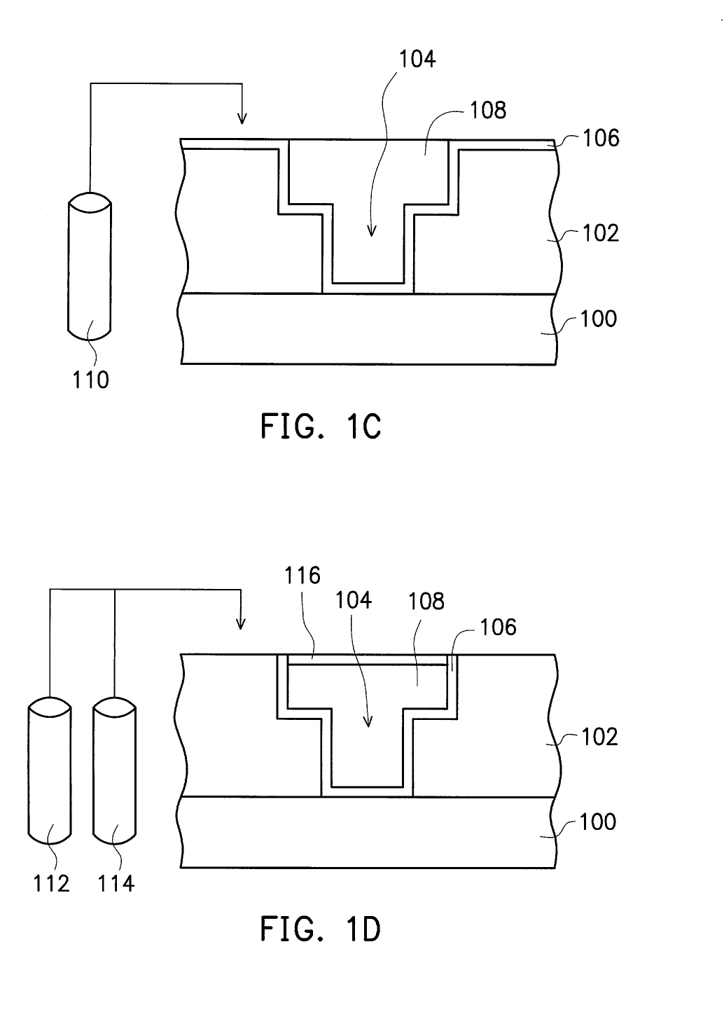

FIGS. 1A to 1D illustrate the method of fabricating a damascene structure according to one preferred embodiment of the present invention.

Referring to FIG. 1A, a substrate 100 is provided (the components of the substrate are not shown in the diagram to simplify the diagram). A dielectric layer 102 is formed on the substrate 100. The dielectric layer 102 can be made of low-K dielectric material, for example, fluorinated organic polymers including, fluorinated hydrocarbon, fluorinated poly arylene ether (FLARE), aromatic polymer or hydrogen silsesquioxane (HSQ). The dielectric layer 102 includes, for example, vapor-phase deposition polymers (VPDP), spin-on polymer (SOP) or spin-on glass (SOG).

The dielectric layer 102 is defined to form an opening 104 by conventional photolithography and etching techniques. The opening 104 is, for example a damascene opening of a dual damascene structure, a trench for a metal conductive wire, a via opening for a plug, a contact opening or any opening of a damascene structure (the diagram shows a damascene opening of a dual damascene structure).

Referring to FIG. 1B, a barrier layer 106 is formed conformally to the profile of the opening 104. For example, the barrier layer 106 can be made of tantalum nitride (TaN). The method for forming the barrier layer 106 comprises placing the wafer in an environment containing nitrogen, which causes tantalum to react into tantalum nitride. Afterward, depositing a layer of tantalum nitride on the surface of a wafer by a magnetrom DC sputtering method. Another method is to use tantalum as a bombarded target with a reaction gases that contains argon and nitrogen gases in the bombardment. The nitrogen atoms that are dissociated from plasma will reactive with tantalum to form tantalum nitride on the surface of the wafer. A metal layer 108 is formed on the barrier layer 106. The metal layer can be formed by, for example, physical vapor deposition (PVD), chemical vapor deposition or sputtering. The metal layer can be made of copper, tungsten and aluminum, for example.

Referring to FIG. 1C, a chemical mechanical polishing process is performed to remove the metal layer 108 with a first slurry 110. The metal layer 108 is polished away until the barrier layer 106 is exposed. The barrier layer 106 acts as a polishing stop layer to remove a portion of the metal layer 108. The slurry 110, for example, can be a metal-polishing slurry that comprises water, abrasive particles, surfactant, buffer solution, and anti-corrosive etc. The surfactant is used for separating the abrasive particles to prevent the abrasive particles clotted or aggregated. The buffer solution is used to control the pH values of the slurry 110. The anti-corrosive is used to prevent the slurry 110 from corroding the metal layer 108.

Referring to FIG. 1D, a solution 114 that can change the zeta potential of the metal layer 108 is added to a second slurry 112 for the polishing process of the barrier layer 106. The oxidant will react with the metal layer 108 to produce an oxide layer 116 with high hardness on the surface of the metal layer 108. The value of the zeta potential of the oxide layer 116 is approximate to the zeta potential value of the carbon-rich particles, and both of them have the same conductivity. Therefore, the carbon-rich particles are prevented from adhering onto the surface of the metal layer 108, thus preventing scratching damages on the surface of the metal layer 108 by the slurry particles and reducing defeats during the manufacture process. The oxide layer 116 can protect the surface of the metal layer 108 and prevent scratching on the metal layer 108.

The oxidant can be added by putting the oxidant directly into the slurry 112, or dissolving the oxidant into the solution 114 and then mixing with the slurry 112 from a different pipeline onto the polished pad.

The solution 114 has a low concentration of oxidant. The oxidant, for example, is KIO₃, H₂O₂, Fe(NO₃), or (NH₄)₂S₂O₈. A concentration of the oxidant in the whole slurry is between 0.1% to 5% approximately.

The slurry 112, for example, can be slurry for the barrier layer, which comprises water, abrasive particles, surfactant, buffer solution, and anti-corrosive etc. The surfactant is used for separating abrasive particles to prevent the abrasive particles clotted or aggregated. The buffer solution is used to control the pH values of the slurry 112. The pH of slurry 112 should be neutral or alkaline. The anti-corrosive is used to prevent the slurry 112 from corroding the metal layer 108.

The oxidant will react with the metal layer 108 to produce an oxide layer 116 with high hardness on the surface of the metal layer 108. The value of the zeta potential of the oxide layer 116 is approximate to the zeta potential value of the carbon-rich particles, and both of them have the same conductivity. Therefore, the carbon-rich particles are prevented from adhering onto the surface of the metal layer 108, thus preventing scratching damages on the surface of the metal layer 108 by the slurry particles and reducing defects during the manufacture process. The oxide layer 116 can protect the surface of the metal layer 108 and prevent scratching on the metal layer 108.

According one preferred embodiment of the present invention, the slurry added with the oxidant for the barrier layer is used for the chemical mechanical polishing process. An experiment is carried out to determine the total defects of the wafer. The total defect count of the wafer that is polished by the slurry without adding oxidant is higher than the total defect count of the wafer that is polished by the slurry with oxidant added. According to the experiment, the total defect count of the wafer that is polished by the slurry without adding oxidant is about 1101, and the total defect count of the wafer that is polished by the slurry with oxidant added is about 22. Therefore, from the result of the experiment, adding oxidant in the slurry can tremendously reduce the total defect count of the wafer.

The present invention provides a method by using a slurry with oxidant added to change the zeta potential value of the metal layer. The scratching caused by the carbon-rich particles to the surface of the metal layer can be tremendously reduced. The reliability and the performance of the device can thus be improved.

It will be apparent to those skilled in the art that various modifications and variations can be made to the structure of the present invention without departing from the scope or spirit of the invention. In view of the forgoing, it is intended that the present invention cover modification and variation of this invention provided they fall within the scope of the following claims and their equivalents.

What is claimed is:

1. A method of fabricating a damascene structure, comprising:
providing a substrate;
forming a dielectric layer on the substrate;
defining the dielectric layer to form an opening, wherein a portion of the substrate is exposed by the opening;
forming a barrier layer conformal to a profile of the opening;
forming a metal layer over the substrate, wherein the metal layer fills the opening and covers the dielectric layer;
performing a first chemical mechanical polishing process with a first slurry to remove the metal layer until the barrier layer is exposed; and
performing a second chemical mechanical polishing process with a second slurry and a solution to remove the barrier layer, wherein the solution can adjust the zeta potential of the metal layer.

2. The method of claim 1, wherein the solution that adjust the zeta potential of the metal layer comprises an oxidant.

3. The method of claim 2, wherein the oxidant is selected from a group consisting of KIO₃, H₂O₂, Fe(NO₃)₃ and (NH₄)₂S₂O₈.

4. The method of claim 2, wherein a concentration of the oxidant in the slurry is 0.1% to 5%.

5. The method of claim 2, wherein the oxidant is either dissolved into the solution and then mixed up with the second slurry on a polishing pad from different pipelines or added directly to the second slurry.

6. The method of claim 1, wherein the dielectric layer is made of a low-K material and is selected from a fluorinated organic polymers group consisting of fluorinated hydrocarbon, fluorinated poly arylene ether aromatic polymer and hydrogen silsesquioxane.

7. The method of claim 1, wherein a material of the metal layer is selected from a group consisting of copper, tungsten and aluminum.

8. The method of claim 1, wherein the pH of the second slurry can be neutral.

9. The method of claim 1, wherein the pH of the second slurry can be alkaline.

10. The method of claim 1, wherein the opening can be a dual damascene opening, a trench for a metal conductive line, a via opening for a plug, a contact opening or an opening for a damascene structure.

11. A method of fabricating a damascene structure, comprising:
providing a substrate, wherein the substrate comprises a dielectric layer with an opening, a barrier layer conformal to a profile of the opening and a metal layer filling up the opening;
performing a first chemical mechanical polishing process with a first slurry to remove the metal layer until the dielectric layer is exposed; and
performing a second chemical mechanical polishing process with a second slurry that comprises an oxidant to remove a portion of the barrier layer, to form a damascene structure.

12. The method of claim 11, wherein the oxidant is either dissolved into a solution and then mixed up with the second slurry on a polishing pad from different pipelines or adding directly to the second slurry.

13. The method of claim 11 wherein the oxidant is selected from a group consisting of KIO₃, H₂O₂, Fe(NO₃)₃ and (NH₄)₂S₂O₈.

14. The method of claim 11 wherein a concentration of the oxidant in the slurry is 0.1% to 5%.

15. The method of claim 11 wherein the pH of the second slurry can be neutral.

16. The method of claim 11, wherein the pH of the second slurry can be alkaline.

17. The method of claim 11, wherein a material of the metal layer is selected from a group consisting of copper, tungsten and aluminum.

18. A slurry for polishing a barrier layer comprises an oxidant, abrasive particles, surfactant, buffer solution, and anti-corrosive.

19. The slurry of claim 18, wherein the oxidant is selected from a group consisting of KIO₃, H₂O₂, Fe(NO₃)₃ and (NH₄)₂S₂O₈.

20. The slurry of claim 18, wherein a concentration of the oxidant in the slurry is 0.1% to 5%.
